(19) United States
(12) Patent Application Publication
(10) Pub. No.: US 2011/0147902 A1
(43) Pub. Date: Jun. 23, 2011

(54) Integrated Circuit Comprising Light Absorbing Adhesive

(75) Inventor: Petrus Johannes Gerardus Van Lieshout, Beek en Donk (NL)

(73) Assignee: Polymer Vision Limited, Eindhoven (NL)

(21) Appl. No.: 12/999,938

(22) PCT Filed: Jun. 19, 2009
(86) PCT No.: PCT/NL2009/050366

§ 371 Date: Feb. 14, 2011

Related U.S. Application Data
(60) Provisional application No. 61/074,490, filed on Jun. 20, 2008.

(51) Int. Cl. H01L 23/552

(52) U.S. Cl. 257/660; 257/E23.114

(57) ABSTRACT

The invention relates to a structure 20 comprising a substrate 12, a chip 16 bonded to the substrate by means of a bonding adhesive, wherein the bonding adhesive comprises light absorbing and/or light reflecting particles for protecting the chip from the ambient light. The adhesive may be used to fill all cavities 13a, 13b, 13c between the chip 16 and the substrate 12. The invention further relates to a display and an electronic apparatus comprising said structure.

### FIELD OF THE INVENTION

The invention relates to a structure comprising an integrated circuit chip arranged on a substrate. The invention further relates to a device, for example a display comprising the structure. The invention still further relates to an electronic apparatus comprising a device provided with the structure.

### BACKGROUND OF THE INVENTION

A structure comprising a chip arranged on a substrate is widely applicable in electronics. In particular, semiconductor integrated circuits are widely used in the field of electronic displays. For the chip a flip-chip integrated circuit may be used. Suitable electrical connections between the lines patterned on the substrate and the chip may be enabled by means of bonding bumps. As a result a cavity between the chip and the substrate is formed so that a surface of the chip facing the substrate is not in contact with the surface of the substrate. Usually, this cavity is filled with a bonding glue or underfill which may be used to redistribute mechanical and thermo-mechanical stresses arising between the chip and the substrate, as well as to provide electrical contact between the bumps of the chip and the substrate.

In the art of integrated circuits it is realized that the chip material may be sensitive to ambient light necessitating undertaking measures to protect the chip from the ambient light. An embodiment of a chip comprising means for protecting the integrated circuit from the ambient light is known from US 2002/0196398. In this particular embodiment a shielding layer is provided between the substrate and the chip fully covering the integrated circuit of the chip. The known shielding layer comprises a refractory metallic layer and a barrier layer adhered to the substrate by means of an adhesive. The known refractory metal layer is encapsulated in the barrier layer. The refractory metallic layer is used to scatter ambient light back towards a source. Alternatively, a non-reflective light-absorbing material may be used, whereby it is preferable that such material has good heat conducting properties.

In an alternative embodiment of the integrated circuit, known from U.S. Pat. No. 6,249,044, a light absorbing layer is provided between the bumps used to electrically couple the chip to the substrate. In this embodiment no underfill is used so that a cavity between the chip and the substrate is left empty. The light absorbing layer is patterned to form a portion of a suitable under-bump layer.

### SUMMARY OF THE INVENTION

It is a disadvantage of the known integrated circuits that complicated measures have to be undertaken to enable light protection of the chip. Additional processing steps required to pattern the light shield layer may have deteriorative effects on the yield of a display comprising such integrated circuits. In addition extra processing costs elevate the manufacturing price.

It is an object of the invention to provide a structure, notably an integrated circuit comprising a chip arranged on a substrate wherein disadvantageous effects of ambient light on the chip are counteracted in a simple and a cost-effective way.

To this end the structure according to the invention comprises:
a substrate;
a chip bonded to the substrate by means of a bonding adhesive,
wherein the bonding adhesive comprises light absorbing and/or light reflective particles for protecting the chip from ambient light.

The technical measure of the invention is based on the insight that by integrating shield protecting functionality with the bonding glue used to attach the chip to the substrate a light protector is arranged automatically during bonding operation thereby not requiring extra processing steps. In this way a simple and cost-effective light protection of the chip is enabled. When the chip is arranged on the substrate using a bump, the bonding adhesive, for example a suitable glue comprising light absorbing and/or light reflecting particles, is arranged in a cavity thus formed between the chip and the substrate.

Preferably, to enable efficient light absorption a concentration of the light absorbing and/or light reflecting particles in the bonding adhesive comprises at least 50% of the volume fraction. It will be appreciated that light reflecting particles may comprise light scattering particles. The light absorbing particles may comprise carbon black particles or any other suitable material. Therefore, instead of adding extra light shields after bonding, the bonding glue itself functions as a light shield protecting further layers. The size of the light absorbing particles is preferably small compared to the conductive particles constituting the bond glue. This prevents worsening of the electrical contact between the substrate patterns and chip bumps. Because thickness of the adhesive layer along a chip surface can be in the order of the bump height, yielding the adhesive layer in a range of 10-30 μm, preferably about 20 μm, light absorbing particles and/or light reflecting particles may be a few micrometer in diameter, preferably less than 1 μm, more preferably less than 100 nm, for example, nano-particles. By way of example, by filling 50% of the volume fraction of the adhesive with the light absorbing particles, for example 20 nm carbon black particles, the transmission of the ambient light will be about 10% of an original value when no light absorbing particles are added. It will be appreciated that selection of a suitable particle size as well as volume fraction of the adhesive which is filled with the absorbing and/or reflecting particles lies within common skills of the artisan, such selection being dependent on desired level of light protection.

A display according to the invention comprises the structure in accordance with the foregoing. In particular embodiment, the display may be reflective or top-emissive. In this case the substrate may be opaque to the ambient light and the bonding glue comprising light absorbing and/or light reflective particles may be arranged at areas substantially laterally to the chip. This has an advantage that only small areas at chip sides have to be filled with the light absorbing adhesive which may additionally reduce manufacturing costs. For this arrangement a top light shield may be desirable to prevent ambient light from affecting the chip from a front surface thereof. It will be appreciated that a display according to the invention may relate either to a rigid or flexible electronic display.

An electronic apparatus according to the invention comprises a display as is described with reference to the foregoing.

These and other aspects of the invention will be discussed in further detail with reference to drawings, wherein like reference signs represent like items.

### BRIEF DESCRIPTION

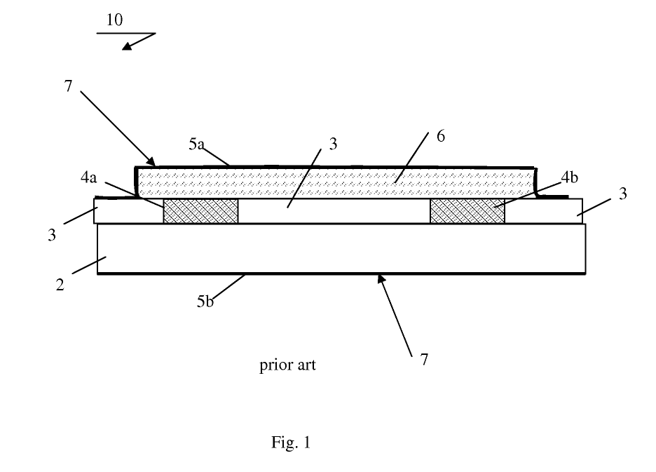

FIG. 1 presents a schematic view of an embodiment of an integrated circuit as known in the art.

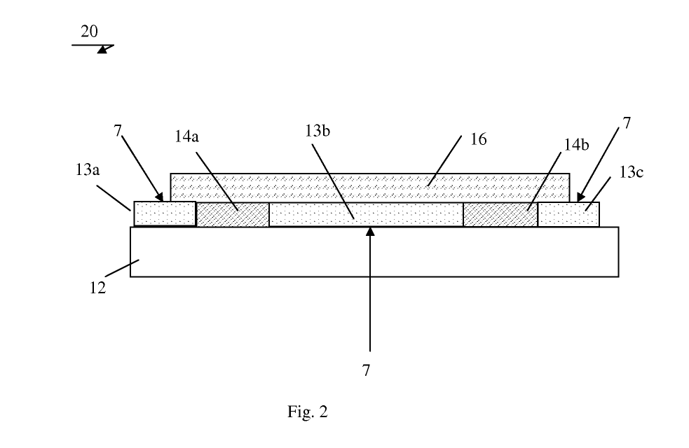

FIG. 2 presents a schematic view of an embodiment of an integrated circuit according to the invention.

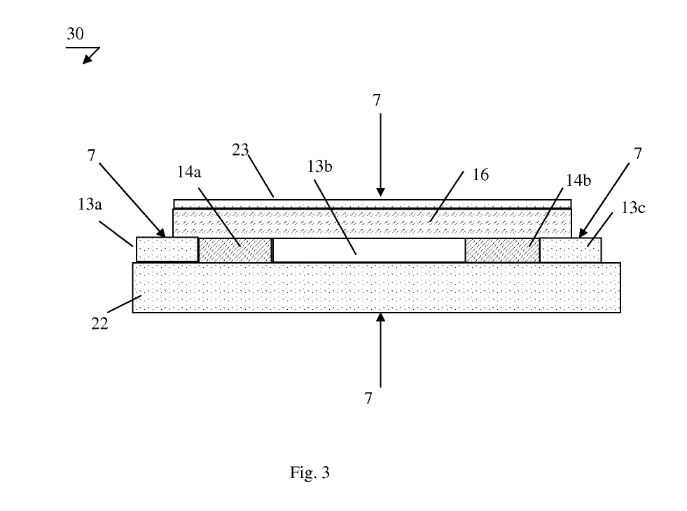

FIG. 3 presents a schematic view of a further embodiment of the integrated circuit according to the invention.

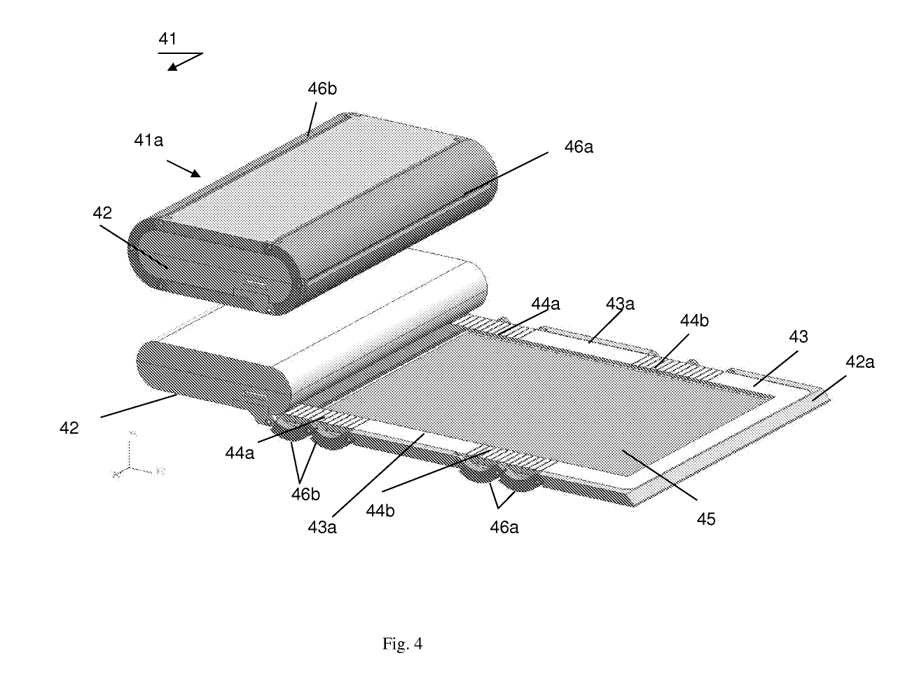

FIG. 4 presents a schematic view of an embodiment of an electronic device according to the invention.

### DETAILED DESCRIPTION

FIG. 1 presents a schematic view of an embodiment of a structure as known in the art. The structure 10, which may be part of a display, comprises a substrate 2 whereon a chip 6 is mounted. Electrical connectivity to the chip 6 is provided by bumps 4a and 4b. The chip 6 is adhered to the substrate 2 by means of a suitable glue 3. The glue is used to fill cavities (not indicated) between a bottom surface of the chip 6 and an upper surface of the substrate 2. Due to the fact that the chip is sensitive to ambient light, the integrated circuit 10 is protected from the ambient light by application of absorbing layers 5a and 5b covering both a front and a rear surface of the integrated circuit 10. Due to the absorbing layers 5a, 5b ambient light 7 does not penetrate the chip 6. As has been explained earlier such set-up is disadvantageous, as the light shielding measures can only be realized in an advanced stage of the processing flow and thus on semi-products that already have high value. Extra processing steps might give rise to yield loss.

FIG. 2 presents a schematic view of an embodiment of an integrated circuit according to the invention. The structure 20 according to the invention solves problems associated with the prior art in that the light shielding function is integrated in the chip bonding adhesive. It will be appreciated that the structure 20 may relate to a suitable chip or a flip chip as known in the art. The structure 20 may comprise a substrate 12 whereto a chip or a flip chip 16 is adhered using a suitable adhesive, comprising light absorbing and/or light reflecting particles (not shown). Electrical connectivity to the chip 16 is enabled using bumps 14a, 14b the thickness of which determines cavities 13a, 13b, 13c between the chip 16 and the substrate 12. In order to prevent ambient light from interacting with the chip 16, the adhesive for adhering the chip 16 to the substrate comprises light absorbing and/or light reflective particles. The adhesive may be used to fill all cavities 13a, 13b, 13c between the chip 16 and the substrate 12. It will be appreciated that a choice of the light absorbing and/or light reflective particles, the volume fraction of the adhesive filled with the light absorbing and/or light reflective particles and the dimension of the light absorbing and/or light reflective particles is determined by a desired net light interception. It will be further appreciated that the net light interception is also influenced by a volume of the cavity conceived to be filled by the adhesive. Full or partially filling is contemplated as well. Due to the fact that the adhesive has also a function of a light interceptor, processing steps of the integrated circuit are simplified resulting in a reduction of processing costs and in reduction of damage to the chip caused by supplementary steps related to provision of light absorbing and/or light reflecting means or additional layers. In order to protect the chip from the ambient light a top light shield 23 may still be necessary.

FIG. 3 presents a schematic view of a further embodiment of the integrated circuit according to the invention. The integrated circuit 30 may comprise a substrate 22 which may be light absorbing. In this case the cavity 13b may be left empty, because there is no need to protect the chip 16 from the ambient light from below. In this configuration, therefore, it suffices to provide light absorbing adhesive in cavities 13a and 13c to protect the chip from ambient light from the periphery. Such configuration may be used in reflective or top-emissive displays. In order to protect the chip from the ambient light a top light shield 23 may still be necessary.

FIG. 4 presents a schematic view of an embodiment of an electronic device according to the invention. The electronic device 41 comprises a housing 42 and a retractable, notably wrappable display 45, preferably arranged on a rigid cover 42a. The rigid cover 42a is arranged to be wound together with the display 45 around the housing 42 to a position 41a. The rigid cover 42a comprises the edge member 43 provided with rigid areas 43a and flexible areas 44a, 44b cooperating with hinges 46a, 46b of the cover 42a. When the display 45 is being retracted to the position wound about the housing 42, the surface of the display 45 may abut the housing 42. Functioning of the display 45 is based on the integrated circuits comprising a substrate, a chip bonded to the substrate by means of a bonding adhesive, wherein the bonding adhesive comprises light absorbing and/or light reflecting particles for protecting the chip from the ambient light, as is described with reference to the foregoing. It will be appreciated that the electronic device comprising the flexible display may also be arranged for storing the flexible display in a housing of the electronic apparatus rolled about a suitable roller. Rollable electronic displays are known in the art and they are also based on integrated circuits. In accordance with the invention such integrated circuits are provided with a chip adhesive, which has light intercepting functionality. It will further be appreciated that the electronic apparatus according to the invention may also comprise a rigid display based on integrated circuits wherein respective chips are bounded to the substrate using a light intercepting adhesive.

It will be appreciated that although specific embodiments of the structure according to the invention are discussed separately for clarity purposes, interchangeability of compatible features discussed with reference to isolated figures is envisaged. While specific embodiments have been described above, it will be appreciated that the invention may be practiced otherwise than as described. The descriptions above are intended to be illustrative, not limiting. Thus, it will be apparent to one skilled in the art that modifications may be made to the invention as described in the foregoing without departing from the scope of the claims set out below.

1. A structure comprising:
a substrate;
a chip bonded to the substrate by a bonding adhesive,
wherein the bonding adhesive comprises light absorbing and/or light reflecting particles for protecting the chip from ambient light.

2. The structure according to claim 1, wherein the chip is arranged on the substrate using at least one bump, the bonding adhesive comprising light absorbing particles arranged in a cavity formed between the chip and the substrate.

3. The structure according to claim 1, wherein the bonding adhesive is arranged as a layer having thickness in a range of 10-30 micrometers.

4. The structure according to claim 1, wherein a concentration of the light absorbing and/or light reflecting particles in the bonding adhesive comprises at least 50% of a volume of the bonding adhesive.

5. The structure according to claim 1, wherein the light absorbing and/or light reflecting particles comprise carbon black particles.

6. A display comprising a structure according to claim 1.

7. The display according to claim 6, wherein the display is reflective or top-emissive, the bonding adhesive comprises light absorbing particles arranged at areas substantially laterally to the chip, the substrate being opaque to the ambient light.

8. The display according to claim 8, further comprising a top light shield.

9. The display according to claim 6, wherein the display is flexible.

10. An electronic apparatus comprising a display according to claim 9.
